(19) United States
(12) Patent Application Publication
(10) Pub. No.: US 2025/0157532 A1
(43) Pub. Date: May 15, 2025

(54) SEMICONDUCTOR MEMORY DEVICE

(71) Applicant: Socionext Inc., Kanagawa (JP)

(72) Inventor: Shinichi MORIWAKI, Yokohama-shi (JP)

(21) Appl. No.: 19/022,682

(22) Filed: Jan. 15, 2025

Related U.S. Application Data
(63) Continuation of application No. PCT/JP2022/030078, filed on Aug. 5, 2022.

(51) Int. Cl. G11C 11/419; G11C 11/418

(52) U.S. Cl. CPC G11C 11/419; G11C 11/418

(57) ABSTRACT

A semiconductor memory device includes a memory cell array and a write circuit having a function of lowering the potential of a bit line connected to a write-target memory cell, and bringing the low potential-side bit line to a negative potential by means of a capacitance in response to a negative potential boost signal. The memory cell array includes a first memory bank and a second memory bank each having a plurality of memory cells. The low potential-side bit line is brought to a negative potential using only a first capacitor element at the time of write into the first memory bank, and using the first capacitor element and a second capacitor element at the time of write into the second memory bank.

### CROSS-REFERENCE TO RELATED APPLICATIONS

This is a continuation of International Application No. PCT/JP2022/030078 filed on Aug. 5, 2022. The entire disclosure of this application is incorporated by reference herein.

### BACKGROUND

The present disclosure relates to a semiconductor memory device.

In recent years, as semiconductor processes are increasingly miniaturized, voltages of semiconductor devices are becoming lower, and this raises a problem of securing stable write operation to static random access memory (SRAM). To address this problem, a write assist technique using a negative bit-line scheme is conventionally known.

Japanese Unexamined Patent Publication No. 2021-140848 discloses a semiconductor memory device having an SRAM of a multi-bank configuration divided into a plurality of banks and an assist circuit commonly connected to the plurality of banks. In the cited patent document, the write assist level (negative potential) is optimized by changing the number of banks at the time of write into the SRAM.

In the semiconductor memory device described in the cited patent document, all banks at maximum are to be connected to a capacitance provided in the assist circuit. Therefore, a large capacitance must be provided for optimizing the write assist level, and this increases the circuit area.

Also, in the multi-bank configuration, when the banks have different sizes from each other, i.e., when the numbers of memory cells connected to the respective bit lines are different from each other, it is difficult to optimize the write assist level, causing a failure to perform normal write in some cases.

An objective of the present disclosure is providing a semiconductor memory device of a multi-bank configuration in which an optimum write assist level is achieved and normal write is achieved with a small-area circuit even though banks have different sizes from each other.

### SUMMARY

According to the first mode of the disclosure, a semiconductor memory device includes: a memory cell array including a first memory bank and a second memory bank each having a plurality of memory cells, each of the plurality of memory cells being connected to a corresponding word line and a corresponding bit line pair, the number of word lines in the first memory bank being smaller than the number of word lines in the second memory bank; and a write circuit having a function of lowering a potential of one bit line of a bit line pair connected to a write-target memory cell, and bringing the low potential-side bit line to a negative potential by means of a capacitance connected to an internal ground line in response to a negative potential boost signal, wherein the capacitance includes a first capacitor element and a second capacitor element each connected to the internal ground line, the low potential-side bit line is brought to a negative potential using only the first capacitor element at the time of write into a memory cell in the first memory bank, and the low potential-side bit line is brought to a negative potential using the first capacitor element and the second capacitor element at the time of write into a memory cell in the second memory bank.

According to the above mode, at the time of write into a memory cell in the first memory bank where the number of rows is comparatively small, the low potential-side bit line is brought to a negative potential using only the first capacitor element. At the time of write into a memory cell in the second memory bank where the number of rows is comparatively large, the low potential-side bit line is brought to a negative potential using both the first capacitor element and the second capacitor element. With this, optimum write assist levels can be secured for the respective write operations into the first memory bank and the second memory bank. It is therefore possible to achieve normal write into the write-target memory cell and also prevent wrong write into a non-target memory cell.

According to the present disclosure, in a semiconductor memory device of a multi-bank configuration, it is possible to achieve an optimum write assist level and achieve normal write with a small-area circuit even though banks have different sizes from each other.

### BRIEF DESCRIPTION OF THE DRAWINGS

FIG. 1 is a functional block diagram showing a configuration example of a semiconductor memory device.

FIG. 2 is a view showing a circuit configuration example of a memory cell in FIG. 1.

FIG. 3 is a view showing a circuit configuration example of a write circuit.

FIG. 4 is a timing chart showing an operation example of the semiconductor memory device.

### DETAILED DESCRIPTION

An embodiment of the present disclosure will be described hereinafter with reference to the accompanying drawings. Note that, in the following description, the same reference character may be used to denote a signal line and a signal passing through the signal line.

### Embodiment

A semiconductor memory device 1 includes a memory cell array 2 and read/write circuits 3.

### —Memory Cell Array—

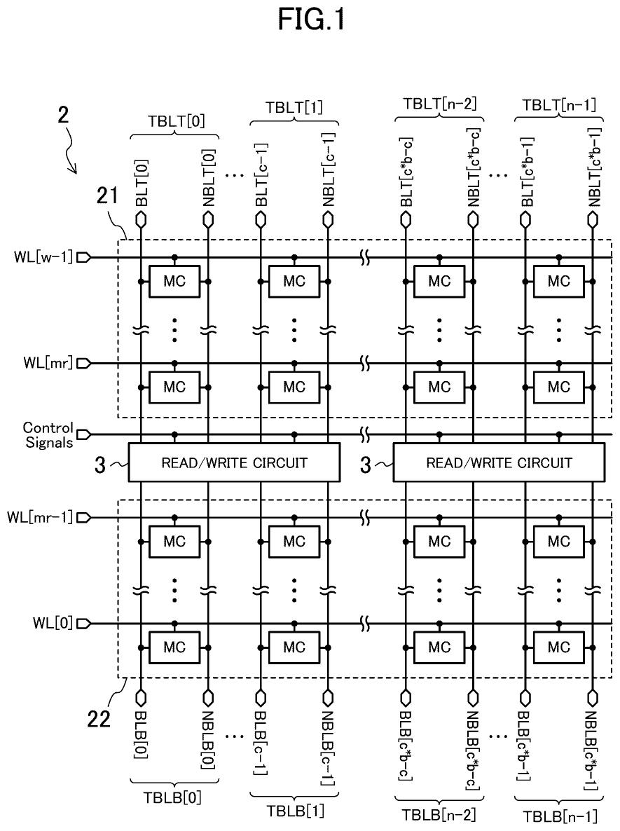

As shown in FIG. 1, the memory cell array 2 includes a first memory bank 21 and a second memory bank 22.

The first memory bank 21 includes a plurality of memory cells MC arranged in an array of [c columns (c is a natural number)×w−mr rows (w is a natural number)×b sets (b is a natural number)]. That is, the first memory bank 21 is configured so that c columns of memory cells as one set are arranged by b sets, totally including [c×b] columns and [c×(w−mr)×b] memory cells MC. In the first memory bank 21, [w−mr] is the number of rows.

The first memory bank 21 includes a plurality of ([w−mr] in FIG. 1) word lines WL extending in the row direction and a plurality of ([c×b] in FIG. 1) bit line pairs TBLT (bit lines BLT and NBLT) extending in the column direction. The memory cells MC are connected to the respective word lines WL and bit line pairs TBLT corresponding to their positions.

The second memory bank 22 includes a plurality of memory cells MC arranged in an array of [c columns (c is a natural number)×mr rows (mr is a natural number)×b sets (b is a natural number)]. That is, the second memory bank 22 is configured so that c columns of memory cells as one set are arranged by b sets, totally including [c×b] columns and [c×mr×b] memory cells MC. In the second memory bank 22, mr is the number of rows.

The second memory bank 22 includes a plurality of (mr in FIG. 1) word lines WL extending in the row direction and a plurality of ([c×b] in FIG. 1) bit line pairs TBLB extending in the column direction crossing the row direction. The memory cells MC are connected to the respective word lines WL and bit line pairs TBLB (bit lines BLB and NBLB) corresponding to their positions.

Here, the number of word lines in the first memory bank 21 is smaller than that in the second memory bank 22. That is, in the example of FIG. 1, the relationship between the numbers of memory cells MC in the two memory banks is [mr>(w−mr)], and the number of rows in the first memory bank 21 is smaller than the number of rows in the second memory bank 22. In other words, the load capacitance of the bit line pairs TBLT in the first memory bank 21 is smaller than the load capacitance of the bit line pairs TBLB in the second memory bank 22.

In the first memory bank 21 and the second memory bank 22, the word lines WL are connected to a row decoder (not shown). The row decoder activates a word line WL corresponding to a row in which a target memory cell MC is included in response to a row address designated from a CPU (not shown).

The bit line pairs TBLT in the first memory bank 21 and the bit line pairs TBLB in the second memory bank 22 are connected to the read/write circuits 3 provided at the corresponding positions. The read/write circuits 3 will be described later.

Note that, in the following description, in some cases, the bit lines BLB and BLT may be simply called the “bit lines BL” collectively, not distinguished from each other. Similarly, the bit lines NBLB and NBLT may be simply called the “bit lines NBL” collectively, and the bit line pairs TBLB and TBLT may be simply called the “bit lines TBL” collectively.

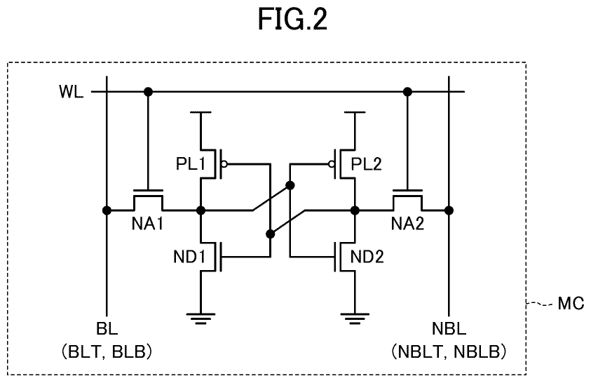

FIG. 2 is a circuit diagram showing an internal configuration of the memory cell MC in FIG. 1. In FIG. 2, the memory cell MC includes n-type transistors NA1 and NA2, p-type transistors PL1 and PL2, and n-type transistors ND1 and ND2.

The n-type transistor NA1 is connected to the word line WL at its gate and to the bit line BL at its source. The n-type transistor NA2 is connected to the word line WL at its gate and to the bit line NBL at its source. The p-type transistor PL1 is supplied with the power supply voltage VDD at its source and connected to the drain of the n-type transistor NA1 at its drain. The n-type transistor ND1 is connected to the gate of the p-type transistor PL1 at its gate, to the drain of the p-type transistor PL1 at its drain, and to the ground potential VSS at its source. The p-type transistor PL2 is connected to the drain of the n-type transistor NA1 at its gate, supplied with the power supply voltage VDD at its source, and connected to the drain of the n-type transistor NA2 at its drain. The n-type transistor ND2 is connected to the gate of the p-type transistor PL2 at its gate, to the drain of the p-type transistor PL2 at its drain, and to the ground potential VSS at its source. The connection node of the gate of the p-type transistor PL1 and the gate of the n-type transistor ND1 is connected to the drain of the n-type transistor NA2.

The p-type transistor PL1 and the n-type transistor ND1 constitute a first inverter, and the p-type transistor PL2 and the n-type transistor ND2 constitute a second inverter. The input terminal of the first inverter is connected to the output terminal of the second inverter, and the output terminal of the first inverter is connected to the input terminal of the second inverter, whereby a latch circuit is formed.

### —Read/Write Circuit—

Referring back to FIG. 1, the read/write circuits 3 are provided between the first memory bank 21 and the second memory bank 22. One read/write circuit 3 is provided every c columns of memory cells, that is, totally b read/write circuits 3 are provided.

The read/write circuits 3 each include a write circuit 30. The write circuit 30 has a first function of lowering the potential of one bit line (BL or NBL) of the bit line pair TBL connected to the write-target memory cell MC and a second function of bringing the low potential-side bit line (BL or NBL) to a negative potential by means of a capacitance connected to an internal ground line WGND in response to negative potential boost signals NWACP0 and NWACP1 to be described later.

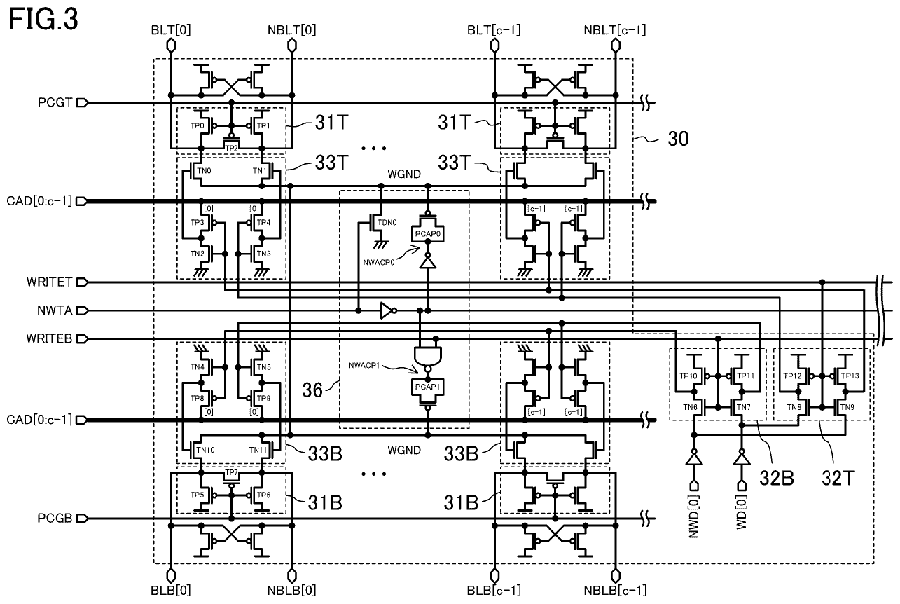

FIG. 3 is a circuit diagram showing a configuration example of the write circuit 30. Note that the configuration of the write circuit 30 is not limited to the one in FIG. 3, but may be any other circuit configuration having the first function and the second function described above.

In the example of FIG. 3, the write circuit 30 includes a write circuit for the first memory bank 21 (precharge circuits 31T, a write driver 32T, and column selection circuits 33T), a write circuit for the second memory bank 22 (precharge circuits 31B, a write driver 32B, and column selection circuits 33B), and a write assist circuit 36.

The precharge circuits 31T each precharge the bit lines BLT and NBLT according to a precharge signal PCGT (hereinafter called the “PCGT signal”). The precharge circuits 31B each precharge the bit lines BLB and NBLB according to a precharge signal PCGB (hereinafter called the “PCGB signal”).

The write driver 32T outputs write data WD[x] or NWD[x](x is an integer equal to or more than 0) based on a write control signal WRITET (hereinafter called the “WRITET signal). The write driver 32B outputs write data WD[x] or NWD[x](x is an integer equal to or more than 0) based on a write control signal WRITEB (hereinafter called the “WRITEB signal). NWD[x] is an inverted signal of WD[x]. Note that, in the following description, the write data signal WD is simply expressed as “WD” and the write data signal NWD is simply expressed as “NW”.

The column selection circuits 33T and 33B have a function of selecting a column that is to be a write target based on a column selection signal CAD[0:c-1].

The column selection circuits 33T each include: a transistor TN0 connected between the bit line BLT and the internal ground line WGND; and transistors TP3 and TN2 that operate the transistor TN0 based on the output of the write driver 32T and the column selection signal CAD[0:c-1].

The column selection circuits 33B each include: a transistor TN10 connected between the bit line BLB and the internal ground line WGND; and transistors TP8 and TN4 that operate the transistor TN10 based on the output of the write driver 32B and the column selection signal CAD[0:c-1].

Note that, in the following description, the column selection signal CAD is simply expressed as “CAD”.

The write assist circuit 36 has a function of bringing the low potential-side bit line to a negative potential by means of a capacitance in response to the negative potential boost signal NWACP0 or NWACP1 generated based on a write assist control signal NWTA (hereinafter called the “NWTA signal”). The capacitance includes a first capacitor element PCAP0 that functions at the time of write into both the first memory bank 21 and the second memory bank 22 and a second capacitor element PCAP1 that functions at the time of write into the second memory bank 22.

In this example, the first capacitor element PCAP0 is a MOS type capacitor element provided between the negative potential boost signal line NWACP0 and the internal ground line WGND. The negative potential boost signal NWACP0 is a signal that changes similarly with the NWTA signal.

The second capacitor element PCAP1 is a MOS type capacitor element provided between the negative potential boost signal line NWACP1 and the internal ground line WGND. The negative potential boost signal NWACP1 is a signal that changes to allow the second capacitor element PCAP1 to function only when the NWTA signal is ‘L’ and the WRITEB signal is ‘H’.

With the configuration described above, at the time of write into the first memory bank 21, when the NWTA signal changes from ‘H’ to ‘L’, only the first capacitor element PCAP0 discharges an electric charge so as to bring the internal ground line WGND to a negative potential. At this time, the second capacitor element PCAP1 does not function.

On the other hand, at the time of write into the second memory bank 22, when the NWTA signal changes from ‘H’ to ‘L’, both the first capacitor element PCAP0 and the second capacitor element PCAP1 discharge an electric charge so as to bring the internal ground line WGND to a negative potential.

Therefore, the capacitance value of the first capacitor element PCAP0 can be adjusted so that the bit line BLT or the bit line NBLT be brought to an optimum negative potential at the time of write into the first memory bank 21. Also, the capacitance value of the second capacitor element PCAP1 can be adjusted so that the bit line BLB or the bit line NBLB be brought to an optimum negative potential using both the capacitance value of the first capacitor element PCAP0 and the capacitance value of the second capacitor element PCAP1 added together, at the time of write into the second memory bank 22. That is, the transistors constituting the first capacitor element PCAP0 and the second capacitor element PCAP1 can be optimized in accordance with the numbers of rows in the first memory bank 21 and the second memory bank 22, respectively. Moreover, it is only required to provide a capacitance just for optimizing the negative potential for the mr rows in the second memory bank 22 using both the first capacitor element PCAP0 and the second capacitor element PCAP1 together. Therefore, the area of the semiconductor memory device 1 can be reduced.

While a PMOS is used as each of the first capacitor element PCAP0 and the second capacitor element PCAP1 in the example of FIG. 3, the capacitor element is not limited to this. For example, an NMOS may be used, or another capacitor element may be used. Also, while the gate of each of the first capacitor element PCAP0 and the second capacitor element PCAP1 is connected to the internal ground line WGND, the source/drain may be connected to the internal ground line WGND.

### —Data Write Operation of Semiconductor Memory Device—

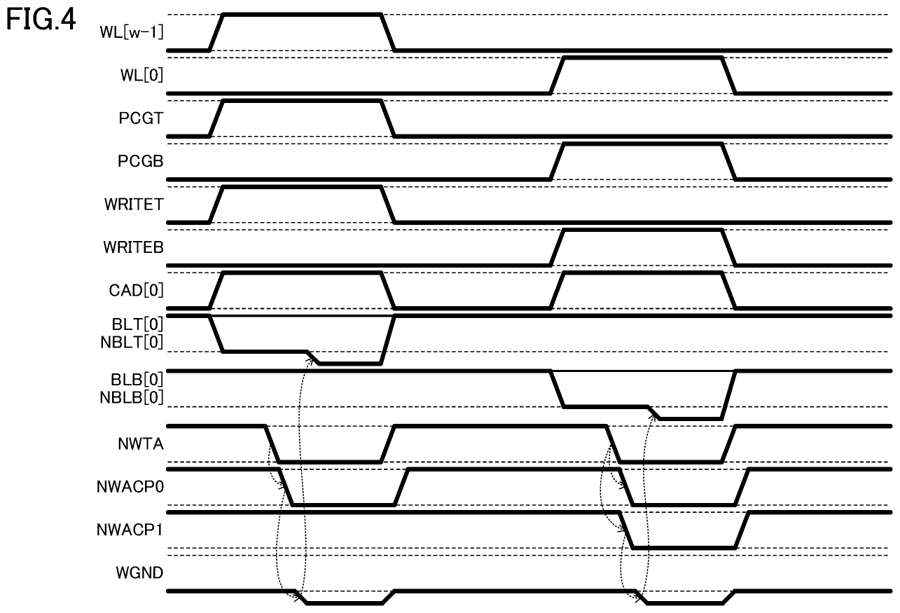

Next, referring to FIGS. 3 and 4, the data write operation into a memory cell MC in the semiconductor memory device 1 will be described. In the following write operation, assume that the capacitance values of the first capacitor element PCAP0 and the second capacitor element PCAP1 have been optimized in accordance with the respective numbers of rows in the first memory bank 21 and the second memory bank 22.

(Write Operation into First Memory Bank)

In this example, the operation to be performed when ‘L’ is written into BLT[0] for the memory cell MC (write target) in the uppermost row (corresponding to WL[w-1] in FIG. 1) and the leftmost column (corresponding to CAD[0] in FIG. 3) among the c columns in the first memory bank 21 will be described.

In the initial state, the NWTA signal is ‘H’. Also, in the initial state, the WRITET signal, the WRITEB signal, the PCGT signal, the PCGB signal, and CAD[0] are ‘L’.

Since the PCGT signal is ‘L’, both BLT[0] and NBLT[0] are precharged to ‘H’. In FIG. 4, BLT[0] is indicated by the bold solid line and NBLT[0] by the thin solid line.

Since the NWTA signal is ‘H’, the internal ground signal WGND is ‘L (0 V)’ via a transistor TDN0, and the sources/drains of the first capacitor element PCAP0 and the second capacitor element PCAP1 are charged to ‘H’. Also, although not shown, WD[0]=‘L’ and NWD[0]=‘H’ are input as write data.

First, WL[w-1] and the PCGT signal, the WRITET signal, and CAD[0], which are control signals, rise from ‘L’ to ‘H’.

With the rise of the WRITET signal from ‘L’ to ‘H’, the gates of the transistor TP13 and the transistor TN9 become ‘H’. Since NWD[0]=‘H’, the gates of the transistor TP3 and the transistor TN2 become ‘L’. Also, since CAD[0]=‘H’, the source of the transistor TP3 is ‘H’. Therefore, the gate of the transistor TN0 becomes ‘H’. With this, since the internal ground signal WGND is ‘L (0 V)’, the bit line BLT[0] falls from ‘H’ to ‘L’.

The timing of the NWTA signal has been adjusted so as to fall from ‘H’ to ‘L’ at the time when the bit line BLT[0] has sufficiently fallen to the ground potential VSS. Therefore, after the bit line BLT[0] has fallen to the ground potential VSS, the NWTA signal falls from ‘H’ to ‘L’, causing the transistor TDN0 to turn off, whereby the internal ground signal WGND is floated in the state of the ground potential VSS.

Also, when the NWTA signal falls from ‘H’ to ‘L’, the NWACP0 signal also falls from ‘H’ to ‘L’, causing the source/drain of the first capacitor element PCAP0 to be discharged, whereby the internal ground signal WGND becomes a negative potential. At this time, since the WRITEB signal remains ‘L’, the NWACP1 signal remains ‘H’ and therefore the source/drain of the second capacitor element PCAP1 is not discharged.

As described above, since the capacitance value of the first capacitor element PCAP0 has been adjusted so that the bit line (BLT in this example) in the first memory bank 21 be brought to an optimum negative potential, the write into the write-target memory cell MC in the first memory bank 21 is performed normally. Also, wrong write into a non-target memory cell MC can be prevented.

(Write Operation into Second Memory Bank)

Next, the operation to be performed when ‘L’ is written into BLB[0] for the memory cell MC (write target) in the lowermost row (corresponding to WL[0] in FIG. 1) and the leftmost column (corresponding to CAD[0] in FIG. 3) among the c columns in the second memory bank 22 will be described.

In the initial state, the NWTA signal is ‘H’. Also, in the initial state, the WRITET signal, the WRITEB signal, the PCGT signal, the PCGB signal, and CAD[0] are ‘L’.

Since the PCGB signal is ‘L’, both BLB[0] and NBLB[0] are precharged to ‘H’. In FIG. 4, BLB[0] is indicated by the bold solid line and NBLB[0] by the thin solid line.

Since the NWTA signal is ‘H’, the internal ground signal WGND becomes ‘L (0 V)’ via the transistor TDN0, allowing the sources/drains of the first capacitor element PCAP0 and the second capacitor element PCAP1 to be charged to ‘H’. Also, WD[0]=‘L’ and NWD[0]=‘H’ are input as write data.

First, WL[0] and the PCGB signal, the WRITEB signal, and CAD[0], which are control signals, rise from ‘L’ to ‘H’.

With the rise of the WRITEB signal from ‘L’ to ‘H’, the gates of the transistor TP10 and the transistor TN6 become ‘H’. Since NWD[0]=‘H’, the gates of the transistor TP8 and the transistor TN4 become ‘L’. Also, since CAD[O]=‘H’, the source of the transistor TP8 is ‘H’. Therefore, the gate of the transistor TN10 becomes ‘H’. With this, since the internal ground signal WGND is ‘L (0 V)’, the bit line BLB[0] falls from ‘H’ to ‘L’.

The timing of the NWTA signal has been adjusted so as to fall from ‘H’ to ‘L’ at the time when the bit line BLB[0] has sufficiently fallen to the ground potential VSS. Therefore, after the bit line BLB[0] has fallen to the ground potential VSS, the NWTA signal falls from ‘H’ to ‘L’, causing the transistor TDN0 to turn off, whereby the internal ground signal WGND is floated in the state of the ground potential VSS.

Also, when the NWTA signal falls from ‘H’ to ‘L’, the NWACP0 signal also falls from ‘H’ to ‘L’, causing the source/drain of the first capacitor element PCAP0 to be discharged. In addition, since the WRITEB signal is ‘H’, the NWACP1 signal also falls from ‘H’ to ‘L’ when the NWTA signal falls from ‘H’ to ‘L’. This causes the source/drain of the second capacitor element PCAP1 to be discharged. That is, the sources/drains of the first capacitor element PCAP0 and the second capacitor element PCAP1 are both discharged, whereby the internal ground signal WGND becomes a negative potential.

As described above, since the capacitance value of the second capacitor element PCAP1 has been adjusted so that the bit line (BLB in this example) in the second memory bank 22 be brought to an optimum negative potential using both the capacitance value of the first capacitor element PCAP0 and the capacitance value of the second capacitor element PCAP1 added together, the write into the write-target memory cell MC in the second memory bank 22 is performed normally. Also, wrong write into a non-target memory cell MC can be prevented.

As described above, according to this embodiment, at the time of write into a memory cell in the first memory bank 21, only the first capacitor element PCAP0 is made to function to bring the low potential-side bit line (BLT in the example of FIG. 4) to a negative potential. Also, at the time of write into a memory cell in the second memory bank 22 where the number of rows is larger than that in the first memory bank 21, both the first capacitor element PCAP0 and the second capacitor element PCAP1 are used to bring the low potential-side bit line (BLB in the example of FIG. 4) to a negative potential. With this, optimum write assist levels can be secured for the respective write operations into the first memory bank 21 and the second memory bank 22. It is therefore possible to achieve normal write into the write-target memory cell MC and also prevent wrong write into a non-target memory cell MC.

According to the present disclosure, in a semiconductor memory device of a multi-bank configuration, it is possible to achieve an optimum write assist level and achieve normal write with a small-area circuit even though banks have different sizes from each other. The present disclosure is therefore very useful.

1. A semiconductor memory device, comprising:
a memory cell array including a first memory bank and a second memory bank each having a plurality of memory cells, each of the plurality of memory cells being connected to a corresponding word line and a corresponding bit line pair, the number of word lines in the first memory bank being smaller than the number of word lines in the second memory bank; and
a write circuit having a function of lowering a potential of one bit line of a bit line pair connected to a write-target memory cell, and bringing the low potential-side bit line to a negative potential by means of a capacitance connected to an internal ground line in response to a negative potential boost signal,
wherein
the capacitance includes a first capacitor element and a second capacitor element each connected to the internal ground line, the low potential-side bit line is brought to a negative potential using only the first capacitor element at the time of write into a memory cell in the first memory bank, and the low potential-side bit line is brought to a negative potential using the first capacitor element and the second capacitor element at the time of write into a memory cell in the second memory bank.

2. The semiconductor memory device of claim 1, wherein
the write circuit selects the write-target memory cell based on a column selection signal.

3. The semiconductor memory device of claim 1, wherein
the first capacitor element and the second capacitor element are each formed of a MOS transistor.
